(19) United States
(12) Patent Application Publication
(10) Pub. No.: US 2017/0221720 A1
(43) Pub. Date: Aug. 3, 2017

(54) APPARATUS AND METHOD FOR TREATING SUBSTRATES

(71) Applicant: PSK INC., Gyeonggi-do (KR)

(72) Inventors: Jeonghee CHO, Hwaseong-si (KR); Hee Sun CHAE, Hwaseong-si (KR)

(73) Assignee: PSK INC., Gyeonggi-do (KR)

(21) Appl. No.: 15/490,033

(22) Filed: Apr. 18, 2017

Related U.S. Application Data
(62) Division of application No. 13/906,438, filed on May 31, 2013.

(30) Foreign Application Priority Data
Jun. 4, 2012 (KR) 10-2012-0059710

(51) Int. Cl. H01L 21/311; H01J 37/32; H01L 21/3213; B08B 7/00; H01L 21/02

(52) U.S. Cl. CPC H01L 21/31116; B08B 7/0035; H01L 21/02087; H01L 21/0209; H01L 21/31138; H01L 21/32136; H01J 37/321; H01J 37/32633; H01J 37/32715; H01J 2237/334; H01J 2237/335

(57) ABSTRACT

Provided are an apparatus and a method for treating substrates. The apparatus includes a process chamber, a support plate to support a substrate inside the process chamber, a gas supply unit to supply a gas into the process chamber, a first plasma generation unit provided to generate plasma inside the process chamber, and a second plasma generation unit provided to generate plasma outside the process chamber. An etching process, an ashing process, an edge cleaning process, and a back-surface cleaning process are sequentially performed on the substrate inside the process chamber.

### CROSS-REFERENCE TO RELATED APPLICATIONS

This application is a divisional of U.S. patent application Ser. No. 13/906,438, filed with the united States Patent and Trademark Office on May 31, 2013, which claims priority under 35 USC §119 to Korean Patent Application No. 10-2012-0059710, filed on Jun. 4, 2012, in the Korean Intellectual Property Office, the entire contents of each of which are incorporated herein in their entirety by reference.

### BACKGROUND OF THE INVENTION

Exemplary embodiments of inventive concepts relate to apparatuses and methods for treating substrates and, more particularly, to an apparatus and a method for treating substrates using plasma.

Various processes are required to manufacture semiconductor devices. For example, an etching process of removing a thin film on a substrate, an ashing process of removing a photoresist layer remaining on the substrate, and a cleaning process of removing byproducts and particles remaining in an edge region or a back surface region of the substrate are sequentially performed. In recent years, each of the etching, ashing, and cleaning processes has been performed mainly using plasma.

In general, an etching process, an ashing process, and a cleaning process are performed in their independently provided apparatuses due to a difference in kind of sources of plasma used, a difference between regions where treatment is performed or a difference in kind of process gases used, respectively. Thus, the etching process, the ashing process, and the cleaning process are sequentially performed on a substrate while an etching apparatus, an ashing apparatus, and a cleaning apparatus are sequentially transferred by a robot or a worker.

However, the above-described typical method requires a number of apparatuses and it takes a long time due to transfer of a substrate between the respective apparatuses.

### SUMMARY OF THE INVENTION

Exemplary embodiments of inventive concepts provide substrate treating apparatuses and substrate treating methods.

A substrate treating apparatus according to an embodiment of the inventive concept may include a process chamber; a support plate to support a substrate inside the process chamber; a gas supply unit to supply a gas into the process chamber; a first plasma generation unit provided to generate plasma inside the process chamber; and a second plasma generation unit provided to generate plasma outside the process chamber. The gas supply unit includes at least two of an ashing gas supply member to supply an ashing processing gas, an etching gas supply member to supply an etching processing gas, and a cleaning gas supply member to supply a cleaning processing gas. The first plasma generation unit includes a bottom electrode provided at the support plate, a top electrode provided inside the process chamber to face the bottom electrode, and a power source to apply power to the bottom electrode. The top electrode includes a baffle where a plurality of injection holes formed vertically therethrough. The baffle is made of a conductive material and grounded.

In an exemplary embodiment, the baffle may have a smaller size than the substrate. The substrate treating apparatus may further include a support plate driver vertically driving the support plate to control a relative distance between the baffle and the support plate.

In an exemplary embodiment, the substrate treating apparatus may further include a lift unit to lift a substrate from the support plate or put down the substrate on the support plate.

In an exemplary embodiment, the lift unit may include a support assembly. The support assembly may include a support pin provided at the outer side of the support plate to vertically move a substrate placed on the support plate; and a support pin driver to drive the support pin and provided to be in contact with an edge region of the substrate.

In an exemplary embodiment, the first plasma generation unit may include a first electrode including the baffle; a second electrode provided in the support plate; and a first power source to apply power to the first electrode or the second electrode. The second plasma generation unit may include a body; an antenna provided to surround the outer circumference of the body; and a second power source to apply power to the antenna. The ashing gas supply member and the etching gas supply member may be provided to supply an ashing processing gas and an etching processing gas through a gas port of the body, respectively.

A substrate treating apparatus according to another embodiment of the inventive concept may include a process chamber; a support plate to support a substrate inside the process chamber; a gas supply unit to supply a gas into the process chamber; a first plasma generation unit provided to generate plasma inside the process chamber; a second plasma generation unit provided to generate plasma outside the process chamber; and a lift unit to lift a substrate from the support plate or put down the substrate on the support plate.

In an exemplary embodiment, the first plasma generation unit may include a first electrode provided in the process chamber; a second electrode provided in the support plate to face the first electrode; and a first power source to apply power to the second electrode. The first electrode may include a baffle where a plurality of injection holes formed vertically therethrough.

In an exemplary embodiment, the second plasma generation unit may include a body; an antenna provided to surround the outer circumference of the body; and a second power to apply power to the antenna.

In an exemplary embodiment, the gas supply unit may include at least two of an ashing gas supply member to supply an ashing processing gas, an etching gas supply member to supply an etching processing gas, and a cleaning gas supply member to supply a cleaning processing gas.

In an exemplary embodiment, the body may include a gas port, a discharge chamber, and a guide pipe. The gas port, the discharge chamber, and the guide pipe may be sequentially provided. The guide pipe may be coupled with the process chamber. The antenna may be provided to surround the outer side of the discharge chamber. The ashing processing gas, the cleaning processing gas, and the etching processing gas may be supplied through the gas port.

In an exemplary embodiment, the baffle may be made of a conductive material and grounded. The baffle may have a size corresponding to that of a center region of the substrate. The support plate may have a size corresponding to that of a center region of the substrate.

In an exemplary embodiment, the substrate treating apparatus may further include a support plate driver to vertically move the support plate.

In an exemplary embodiment, the lift unit may include a support assembly. The support assembly may include a support pin provided at the outer side of the support plate to vertically move a substrate placed on the support plate; and a support pin driver to drive the support pin and provided to be in contact with an edge region of the substrate.

In an exemplary embodiment, the lift unit may further include a lift assembly. The lift assembly may include a lift pin inserted into a pinhole formed in the support plate; and a lift pin driver to drive the lift pin. The lift pin may be provided to be in contact with the center region of the substrate.

A substrate treating method according to an embodiment of the inventive concept may include sequentially performing at least two of an etching process, an ashing process, and a cleaning process while a substrate is provided inside the same process chamber. The etching process may be performed inside the process chamber by generating plasma from an etching processing gas using a first plasma generation unit. The ashing process may be performed outside the process chamber by generating plasma from an ashing processing gas using a second plasma generating unit and supplying the plasma into the process chamber. The cleaning process may be performed inside the process chamber by generating plasma from a cleaning processing gas using the first plasma generation unit.

In an exemplary embodiment, the etching process may further include primarily generating plasma outside the process chamber using the second plasma generation unit.

In an exemplary embodiment, the ashing process may further include secondarily generating plasma inside the process chamber using the first plasma generation unit.

In an exemplary embodiment, a baffle where an injection hole is vertically formed may be provided inside the process chamber. The baffle may be grounded. The etching processing gas or the ashing processing gas may be supplied to the substrate through the injection hole of the baffle.

In an exemplary embodiment, the first plasma generation unit may include a first electrode provided in the process chamber and a second electrode provided in the process chamber to face the first electrode, the first electrode including a grounded baffle where an injection hole is formed vertically therethrough and the second electrode being provided in a support plate to support the substrate. The cleaning process may further include an edge cleaning process to clean an edge region of the substrate. The baffle may have a size corresponding to that of a center region of the substrate and is disposed to face the center region of the substrate. A distance between the substrate and the baffle may be shorter than a plasma sheath region during the edge cleaning process.

In an exemplary embodiment, the first plasma generation unit may include a first electrode provided in the process chamber and a second electrode provided in the process chamber to face the first electrode. The first electrode may include a grounded baffle where an injection hole is formed vertically therethrough, and the second electrode may be provided in a support plate to support the substrate. The cleaning process may further include a back-surface cleaning process to clean a back surface of the substrate. The substrate may be spaced apart from the support plate at a longer distance than a plasma sheath region during the back-surface cleaning process.

In an exemplary embodiment, the edge region of the substrate may be support by a support pin provided at the outer circumference of the support plate during the back-surface cleaning process.

A substrate treating method according to another embodiment of the inventive concept may include putting a substrate into a process chamber; performing an etching process on the substrate by generating plasma from an etching processing gas inside process chamber; performing an ashing process on the substrate by generating plasma from an ashing treating process outside the process chamber and supplying the plasma into the process chamber; performing a cleaning process on the substrate by generating plasma from a cleaning processing gas inside the process chamber; and taking out the substrate to the outside of the process chamber.

In an exemplary embodiment, the cleaning process may include an edge cleaning process to clean an edge region of the substrate. A grounded baffle where an injection hole is vertically formed may be provided in the process chamber. The baffle may have a size corresponding to that of a center region of the substrate. A distance between the substrate and the baffle may be shorter during the edge cleaning process than during the etching process and the ashing process.

In an exemplary embodiment, the distance between the substrate and the baffle may be shorter than a plasma sheath region during the edge cleaning process, and the distance between the substrate and the baffle may be longer than the plasma sheath region during the etching process and the ashing process.

In an exemplary embodiment, the cleaning process may further include a back-surface cleaning process to clean a back surface region of the substrate. The etching process and the ashing process may be performed on the substrate while the substrate is placed on a support plate. The back-surface process may be performed on the substrate while the substrate is spaced apart from the support plate.

In an exemplary embodiment, the edge region of the substrate may be supported by a support pin provided at the outer circumference of the support plate during the back-surface cleaning process.

### BRIEF DESCRIPTION OF THE DRAWINGS

Inventive concepts will become more apparent in view of the attached drawings and accompanying detailed description. The embodiments depicted therein are provided by way of example, not by way of limitation, wherein like reference numerals refer to the same or similar elements. The drawings are not necessarily to scale, emphasis instead being placed upon illustrating aspects of inventive concepts.

FIG. 1 illustrates a substrate treating apparatus according to an embodiment of the inventive concept.

FIG. 2 is a flowchart illustrating a method for treating a substrate using the substrate treating apparatus illustrated in FIG. 1.

FIG. 3 illustrates a state where an etching process is performed in the substrate treating apparatus illustrated in FIG. 1.

FIG. 4 illustrates a state where an ashing process is performed in the substrate treating apparatus illustrated in FIG. 1.

FIG. 5 illustrates a state where an edge cleaning process is performed in the substrate treating apparatus illustrated in FIG. 1.

FIG. 6 illustrates a state where a back-surface cleaning process is performed in the substrate treating apparatus illustrated in FIG. 1.

FIGS. 7 and 8 illustrate modified embodiments of the substrate treating apparatus illustrated in FIG. 1, respectively.

### DETAILED DESCRIPTION

Exemplary embodiments of the inventive concepts will now be described more fully with reference to the accompanying drawings, in which exemplary embodiments of the inventive concept are shown. Exemplary embodiments of the inventive concept may, however, be embodied in many different forms and should not be construed as limited to the embodiments set forth herein. Rather, these exemplary embodiments of the inventive concepts are provided so that this description will be thorough and complete, and will fully convey the concept of exemplary embodiments of the inventive concepts to those of ordinary skill in the art.

In exemplary embodiments of the inventive concept, a substrate may be a wafer. However, the inventive concept is not limited thereto and a substrate may be another type of substrate such as a glass substrate.

In exemplary embodiments of the inventive concepts, a center region of a substrate means a region where a valid chip is formed, and an edge region of the substrate means a region where a valid chip is not formed.

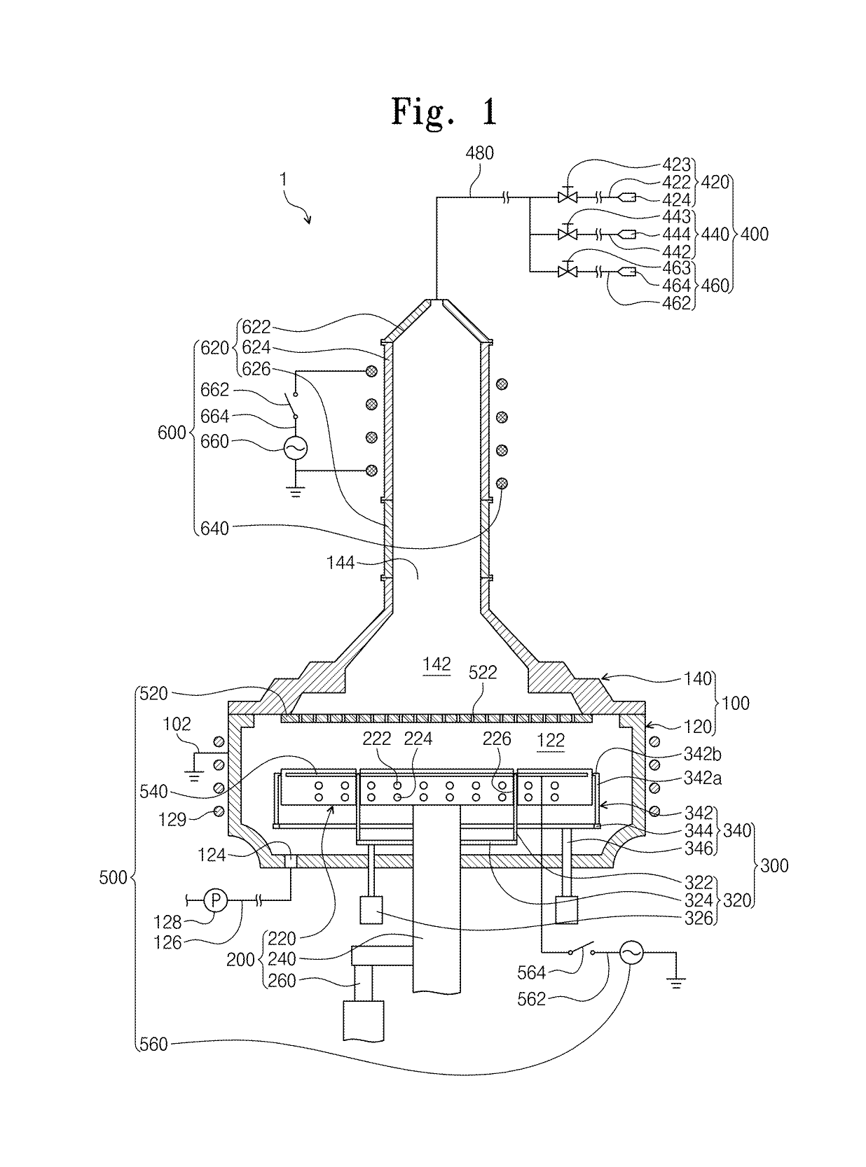

FIG. 1 illustrates a substrate treating apparatus 1 according to an embodiment of the inventive concept. The substrate treating apparatus 1 performs multiple processes on a substrate W using plasma. In an exemplary embodiment, the substrate treating apparatus 1 sequentially performs an etching process, an ashing process, and a cleaning process using plasma. The cleaning process includes an edge cleaning process and a back-surface cleaning process that are sequentially performed.

Referring to FIG. 1, the substrate treating apparatus 1 includes a process chamber 100, a support unit 200, a lift unit 300, a gas supply unit 400, a first plasma generation unit 500, and a second plasma generation unit 600.

The process chamber 100 includes a housing 120 and a cover 140.

The housing 120 has a top-open processing space 122 thereinside. A substrate W is placed in the processing space 122 during a process, and multiple processes are performed in the processing space 122. The housing 120 may be roughly cylindrical. An opening (not shown) is formed in the sidewall of the housing 120. A substrate W enters and exits the housing 120 through the opening. The opening may be opened and closed by an opening and closing member (not shown) such as a door (not shown). An exhaust hole 124 is formed on a bottom surface of the housing 120. An exhaust line 126 is connected to the exhaust hole 124. A pump 128 is mounted on the exhaust line 126. The pump 128 adjusts an inner pressure of the housing 120 to a process pressure. Remaining gases and byproducts inside the housing 120 are exhausted to the outside of the housing 120 through the exhaust line 126. A wall heater 129 may be provided on the outside of the housing 120. If necessary, the wall heater 129 may be provided in the outer wall of the housing 120.

The cover 140 is disposed to be in contact with the upper end of the housing 120 and seals the open top of the housing 120 from the outside. An inflow space 142 is formed inside the cover 140. An inlet 144 is formed at the upper end of the cover 140. A gas or plasma generated outside the process chamber 100 flows into the chamber 100 through the inlet 144. The inflow space 142 is provided such that a gas flow path is downwardly widened. In an exemplary embodiment, the cover 140 may be roughly conic.

The process chamber 100 is made of a conductive material. The process chamber 100 may be grounded through a ground line 102. Both the housing 120 and the cover 140 may be made of a conductive material. In an exemplary embodiment, the housing 120 and the cover 140 may be made of an aluminum material.

The support unit 200 supports a substrate W. The support unit 200 includes a support plate 220, a support shaft 240, and a support plate driver 260. The support plate 220 is disposed in the processing space 122 and is disk-shaped. The support plate 220 is supported by the support shaft 240. The substrate W is placed on a top surface of the support plate 220. The top surface of the support plate 220 may have a smaller size than the substrate W. In an exemplary embodiment, the top surface of the support plate 220 may have a size corresponding to that of a center region of the substrate W. A heating member 222 may be provided inside the support plate 220. In an exemplary embodiment, the heating member 222 may be a hot wire. The heating member 222 is provided to heat the substrate W to a temperature of about 300 degrees centigrade or higher. In addition, a cooling member 224 may be provided inside the support plate 220. In an exemplary embodiment, the cooling member 224 may be a cooling line along which cooling water flows. The heating member 222 heats a substrate W to a predetermined temperature, and the cooling member 224 forcibly cools the substrate W.

The support plate driver 260 allows the substrate 220 to vertically move. Due to the vertical movement of the substrate, a distance between the substrate W placed on the support plate 220 and a baffle 520 (explained later) is adjusted. The support plate driver 260 may be one of various types of drivers such as a motor and a cylinder. The support plate driver 260 may be directly combined with the support shaft 240 to move the support plate 220, as shown in FIG. 1.

The lift unit 300 includes a lift assembly 320 and a support assembly 340.

The lift assembly 320 receives a substrate W from a robot (not shown) externally transferred into the process chamber 100 and loads the substrate W on the support plate 220. Alternatively, the lift assembly 320 unloads a processed substrate W from the support plate 220 and takes over the substrate W to the robot. The lift assembly 320 includes a plurality of lift pins 322, a base 324, and a lift pin driver 326. The base 324 may be roughly arc-shaped. In an exemplary embodiment, the base 324 may be disposed to surround the support shaft 240. A plurality of lift pins 322 are mounted on a top surface of the base 324. The plurality of lift pins 322 may have the same shape and size. Each of the lift pins 322 may be “ [symbol] ” shaped and have an upwardly convex upper end. The lift pin 322 may be made of an insulating material. In an exemplary embodiment, the lift pin 322 may be made of a ceramic material. When the lift pin 322 comes in contact with the substrate W, it may come in contact with a center region of the substrate W. A plurality of pinholes 226 are provided to vertically penetrate the support plate 220. The plurality of pinholes 226 are formed at positions corresponding to the plurality of lifts 322, respectively. A single lift pin 322 is inserted into a single pinhole 226. The lift pin driver 326 lifts the base 324 such that the pinhole 226 moves between a standby position and a support position. The standby position is a position where the upper end of the pinhole 226 is inserted into the pinhole 226, and the support position is a position where the upper end of the pinhole 226 protrudes from the top surface of the support plate 220.

The support assembly 340 supports a substrate W during a cleaning process that will be explained later. The support assembly 340 includes a plurality of support pins 342, a base 344, and a support pin driver 346. The base 344 may be roughly arc-shaped. In an exemplary embodiment, the base 344 may be disposed to surround the support shaft 240. A plurality of support pins 342 are mounted on a top surface of the base 344. The plurality of support pins 342 are provided outside the support plate 220. A support pin 342 is provided to be in contact with an edge region of the substrate W. A plurality of support pins 342 may have the same shape and size. The support pin 342 is made of the same material as the lift pin 322. Each of the support pins 342 includes a vertical portion 342a and a support portion 342b. The vertical portion 342a is provided to protrude straight upward from the base 344. The support portion 342b is provided to protrude toward the support plate 220 from an upper end of the vertical portion 342a. An upper end of the support portion 342b may be roughly a plane.

The gas supply unit 400 supplies a gas used in a process. The gas supply unit 400 includes an etching gas supply member 420, an ashing gas supply member 440 and a cleaning gas supply member 460.

The etching gas supply member 420 supplies an etching processing gas used when an etching process is performed on a substrate W. The etching processing gas may include a fluorine gas (F), a fluorine-containing gas, a chlorine gas (Cl), a chlorine-containing gas or a mixed gas thereof. The etching gas supply member 420 includes an etching gas supply line 422 and an etching gas storage 424. The etching gas supply line 422 may be connected to a gas port 622 of a second plasma generation unit 424 that will be explained later. A valve 423 is mounted on the etching gas supply line 422 to open and close a gas flow path therein or control a gas flow rate.

The ashing gas supply member 440 supplies an ashing processing gas used when an ashing process is performed on a substrate W. The ashing processing gas may include an oxygen gas (O₂), a nitrogen gas (N₂), a hydrogen gas (H₂), an ammonium gas (NH₃) or a mixed gas thereof. The ashing gas supply member 440 includes an ashing gas supply line 442 and an ashing gas storage 444. The ashing gas supply line 442 may be connected to the gas port 622 of the second plasma generation unit 600 that will be explained later. A value 443 may be mounted on the ashing gas supply line 442 to open and close a gas flow path therein or control a gas flow rate.

The cleaning gas supply member 460 supplies a cleaning processing gas used when a cleaning process is performed on a substrate W. The cleaning processing gas may include an oxygen gas (O₂), a nitrogen gas (N₂), an argon gas (Ar) or a mixed gas thereof. The cleaning gas supply member 460 includes a cleaning gas supply line 462 and a cleaning gas storage 464. The cleaning gas supply line 462 may be connected to the gas port 622 of the second plasma generation unit 600 that will be explained later. A value 463 may be mounted on the cleaning gas supply line 462 to open and close a gas flow path therein or control a gas flow rate.

In an exemplary embodiment, as shown in FIG. 1, a main line 480 may be directly connected to the gas port 622 and each of the supply lines 422, 442, and 462 may be provided to branch from the main line 480. Optionally, each of the supply lines 422, 442, and 462 may be directly connected to the gas port 622.

In FIG. 1, it shown that each of the supply members 420, 440, and 460 includes one gas line and one gas storage. However, when a plurality of kinds of gases are used in each process, each of the supply members 420, 440, and 460 may include a plurality of gas lines and a plurality of gas storages.

In addition, when some of the etching processing gas, the ashing processing gas, and the cleaning processing gas use the same kind of gas, some of the supply members 420, 440, and 460 may not be provided.

The first plasma generation unit 500 may be used to generate plasma from the etching processing gas, the ashing processing gas, and the cleaning processing gas inside the housing 120.

The first plasma generation unit 500 includes a first electrode 520, a second electrode 540, and a first power source 560. The first electrode 520 and the second electrode 540 are disposed to vertically face each other. The first electrode 520 may be disposed to be higher than the second electrode 540. In an exemplary embodiment, the first electrode 520 may be a baffle 520 made of a conductive material. The baffle 520 may be disk-shaped. The baffle 520 may be coupled to a bottom surface of the cover 140. The baffle 520 may be in contact with the cover 140 to be electrically connected to the cover 140. In an exemplary embodiment, the baffle 520 may be made of an anodized aluminum (Al) material. The baffle 520 may have a smaller size than the substrate W. In an exemplar embodiment, the baffle 520 may have a size corresponding to that of the central region of the substrate W.

Optionally, a conductive structure may be provided between the process chamber 100 and the baffle 520, and the baffle 520 may be coupled to the process chamber 100 through the conductive structure. A plurality of injection holes 522 are formed at the baffle 520 to extend from an upper end to a lower end of the baffle 520. A gas externally flowing into the inflow space inside the cover 140 may flow to the processing space 122 inside the housing 120 through the injection hole 522. The second electrode 540 may be provided in the support plate 220. The second plate 540 may be a conductive plate.

The first power source 560 applies power to the first electrode 520 or the second electrode 540. In an exemplary embodiment, the first electrode 520 may be grounded and the first power 560 may be connected to the second electrode 540 through a radio-frequency (RF) line 562. A switch 564 may be provided on the RF line 562. The first power 560 may apply an RF bias to the second electrode 540.

Optionally, the baffle 520 may be made of an insulating material. For example, the baffle 520 may be made of a quartz material. In this case, the first plasma generation unit 500 may include the second electrode 540 and the first power source 560 without a first electrode.

The second plasma generation unit 600 may be used to generate plasma from an etching processing gas and an ashing processing gas. The second plasma generation unit 600 is disposed outside the process chamber 100. In an exemplary embodiment, the second plasma generation unit 600 includes a body 620, an antenna 640, and a second power source 660. The body 620 includes a gas port 622, a discharge chamber 624, and a guide pipe 626. The gas port 622, the discharge chamber 624, and the guide pipe 626 are provided sequentially in a top-to-bottom direction. The gas port 622 receives various kinds of gases from the gas supply unit 400. The discharge chamber 624 has a hollow cylindrical shape. When viewed from the top, a space inside the discharge chamber 624 is smaller than a space inside the housing 120. Plasma is generated from the ashing processing gas or the etching processing gas inside the discharge chamber 624. The guide pipe 626 supplies the plasma generated inside the discharge chamber 624 to the housing 120. The guide pipe 626 is coupled with the cover 140. The discharge chamber 624 and the guide pipe 626 may be coupled with each other after they are independently manufactured. Optionally, the guide pipe 626 may be provided to merge with the discharge chamber 624 and extend downwardly from the discharge chamber 624.

The antenna 640 is provided outside the discharge chamber 624 to surround the discharge chamber 624 two or more times. One end of the antenna 640 is connected to the second power source 660, and the other end thereof is grounded. The second power source 660 applies power to the antenna 640 through a radio-frequency (RF) line 662. A switch 664 may be provided on the RF line 662. In an exemplary embodiment, the second power source 660 may apply RF power or a microwave to the antenna 640.

In the foregoing embodiment, the second plasma generation unit 600 is provided as an inductively-coupled plasma (ICP) source. However, the second plasma generation unit 600 may have a structure to apply a microwave to an electrode, an inductively-coupled plasma source structure with a ferrite core or a structure with capacitively-coupled plasma source.

The ashing processing gas may further include a trifluoride nitrogen gas (NF₃). The trifluoride nitrogen gas is introduced through the gas port 622 to be excited into plasma inside the discharge chamber 624. Optionally, the trifluoride nitrogen gas may be supplied to a path along which the plasma generated inside the discharge chamber 624 is supplied to the process chamber 100. In an exemplary embodiment, the trifluoride nitrogen gas may be supplied to the discharge chamber 624 at a lower position than the antenna 640.

In general, plasma includes ions, electrons, and radicals. In the plasma supplied from the second plasma generation unit 600 to the process chamber 100, ions and electrons are prevented from flowing into the process chamber 122 by the baffle 520 and radicals are supplied to the processing space 122 through the injection hole 522.

Hereinafter, a method of performing a plasma process using the substrate treating apparatus 1 in FIG. 1 will now be described in detail. A controller controls elements of the substrate treating apparatus 1. For example, the controller controls whether power is applied in the first plasma generation unit 500 and the second plasma generation unit 600, the magnitude of the power, opening/closing and a gas flow rate of the valves 423, 443, and 463 provided for the gas supply unit 300, and operations of the lift pin driver 326, the support pin driver 346, and the support plate driver 260.

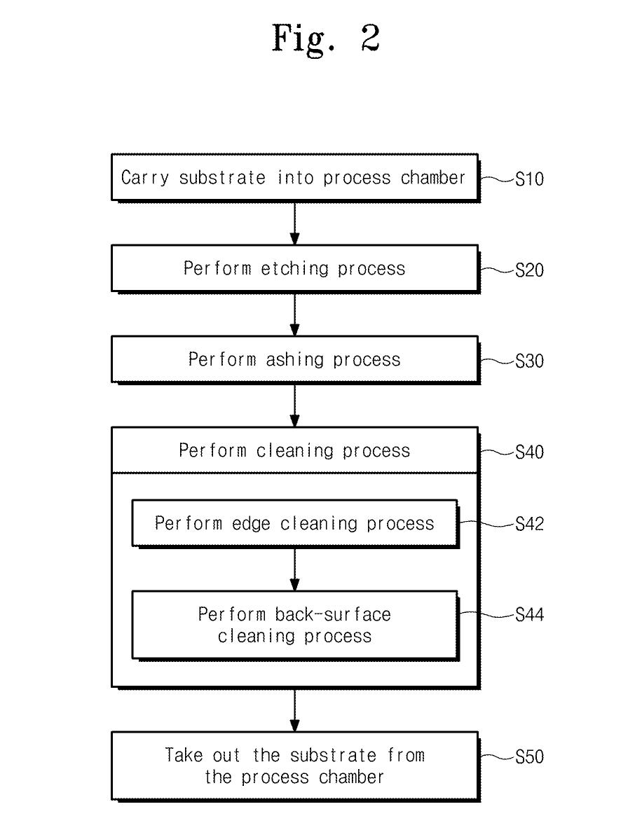

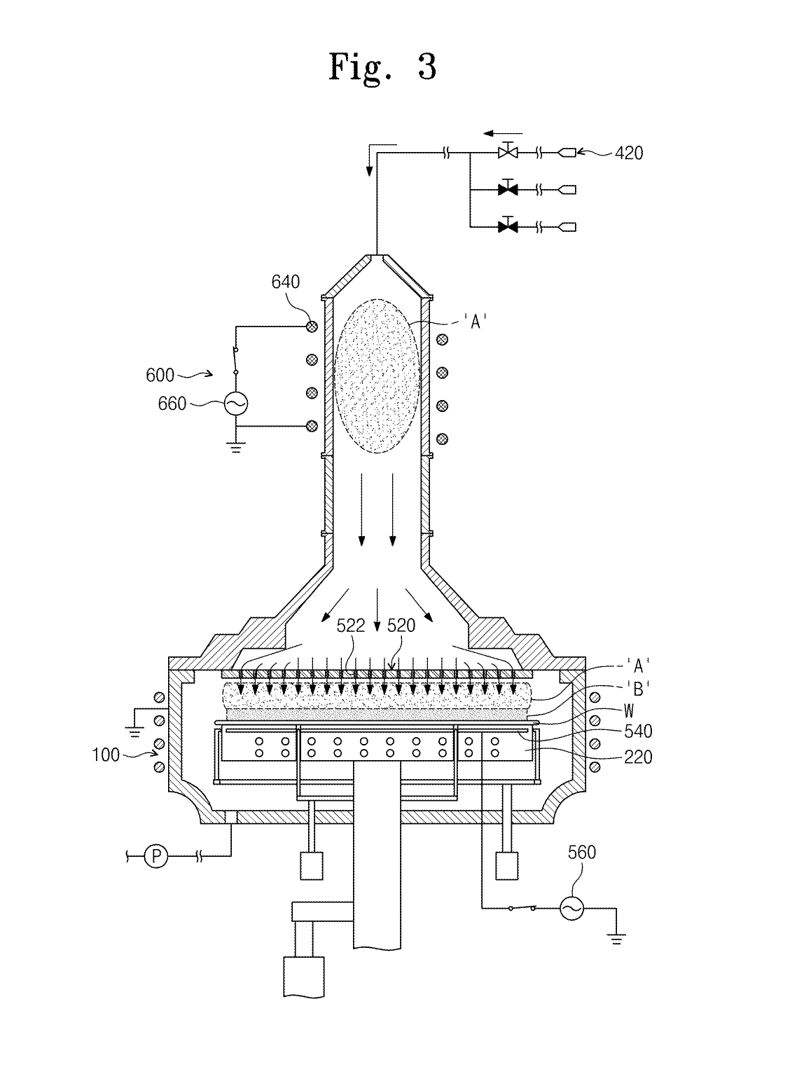

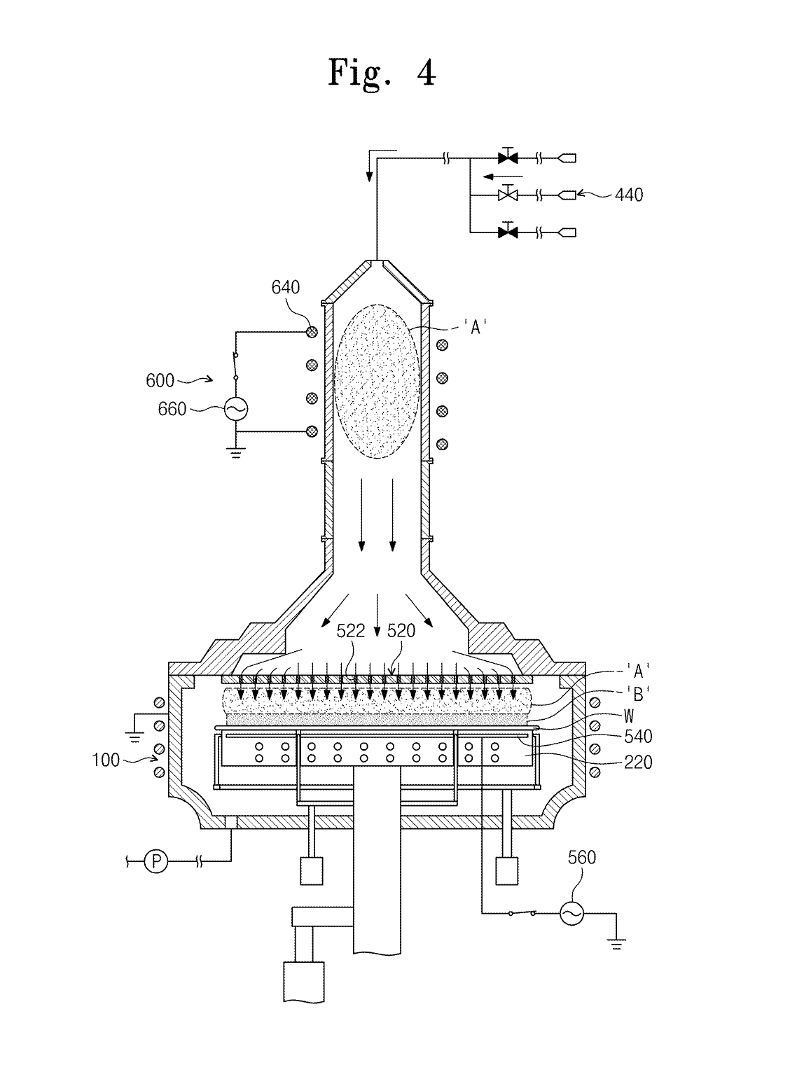

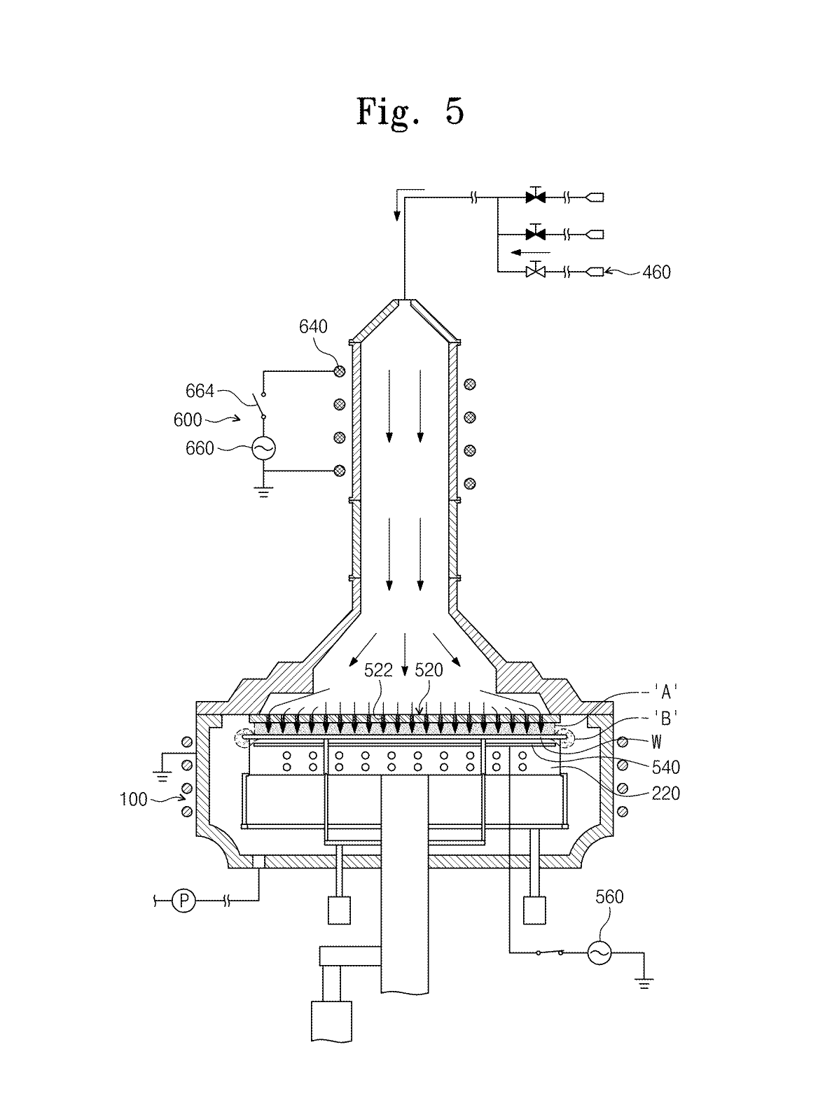

FIG. 2 is a flowchart illustrating a method for treating a substrate W. FIGS. 3 to 6 are flowcharts illustrating the processes of treating a substrate W, respectively. More specifically, FIG. 3 illustrates a state where an etching process is performed, FIG. 4 illustrates a state where an ashing process is performed, and FIG. 5 illustrates a state where an edge cleaning process is performed. In FIGS. 3 to 6, a solid valve is in a closed state while a hollow valve is in an open state. In FIGS. 3 to 6, an “A” region is a plasma-generated region and a “B” region is a plasma sheath region.

First, a substrate W is transferred into the process chamber 100 by a transfer robot (S10). At this point, the lift pin 226 is disposed to protrude upwardly from the support plate 220. Descent of the transfer robot allows the substrate W to be taken over to the lift pin 226. The transfer robot travels to the outside of the process chamber 100, and the lift pin 226 is descended to place the substrate W on the support plate 220.

Next, an etching process is performed on the substrate W (S20). An etching target layer on the substrate W is removed during the etching process. The etching target layer may be one of various types of layers such as a polysilicon layer, a silicon oxide layer, a silicon nitride layer, and a native oxide layer.

Referring to FIG. 3, the substrate W remains placed on the support plate 220 during the etching process. An etching processing gas is supplied to the second plasma generation unit 600 from the etching gas supply unit 420, and power is applied to the antenna 640 from the second power source 660. Plasma A is primarily generated from the etching processing gas inside the discharge chamber 624. The plasma flows to the process chamber 100. Ions and electrons are prevented from flowing into the processing space 122 by the baffle 520, and radicals flows into the processing space 122 through the injection hole 522 of the baffle 520. An RF bias is applied to the second electrode 540 from the first power source 560. In the processing space 122, plasma A is secondarily generated from the etching processing gas.

The substrate W and the baffle 520 are kept at a first distance that is longer than the plasma sheath region B formed over the substrate W. Although a size of the plasma sheath region B varies depending on various process parameters, the plasma sheath region B is formed to have a size ranging from several millimeters (mm) to tens of millimeters (mm). For example, the plasma sheath region B may be formed to have a size ranging from about 0.1 mm to about 30 mm. Thus, the first distance may be greater than about 0.1 mm. The plasma generated from the etching processing gas reacts to an etching target layer on the substrate W to remove the etching target layer.

During the etching process, an internal temperature of the process chamber 100 may be about a room temperature to 60 degrees centigrade and an internal pressure of the process chamber 100 may be maintained at hundreds of milliTorr (mTorr). The temperature and the pressure are not limited thereto.

Then, an ashing process is performed (S30). A photoresist layer on the substrate W is removed during the ashing process.

The ashing processing gas is supplied to the second plasma generation unit 600 during the ashing process. The ashing processing gas is supplied to the second plasma generation unit 600 from the ashing gas supply member 440, and power is applied to the antenna 640 from the second power source 660. Plasma A is primarily generated from the ashing processing gas inside the discharge chamber 624. The plasma A flows to the process chamber 100. Ions and electrons are prevented from flowing into the processing space 122 by the baffle 520, and radicals flows into the processing space 122 through the injection hole 522 of the baffle 520. An RF bias is applied to the second electrode 540 from the first power source 560. In the processing space 122, plasma A is secondarily generated from the etching processing gas.

Referring to FIG. 4, the substrate W remains placed on the support plate 220 during the ashing process. The substrate W on the support plate 220 and the baffle 520 are kept at the above-mentioned first distance. In an exemplary embodiment, a temperature of the process chamber 100 is about 250 to 300 degrees centigrade and an internal pressure of the process chamber 100 may be maintained at hundreds of milliTorr (mTorr). However, the temperature and the pressure are not limited thereto.

Then, a cleaning process is performed (S40). An edge cleaning process is performed first (S42). Byproducts and particles remaining in the edge region of the substrate W are removed during the edge cleaning process.

Referring to FIG. 5, during the edge cleaning process, the substrate W remains placed on the support plate 220 and the support plate 220 is lifted by the support plate driver 260. The substrate and the baffle 520 are kept at a second distance that is shorter than the first distance. In an exemplary embodiment, the second distance may be a distance where only a plasma sheath region B (region where no plasma exists) is formed between the baffle 520 and the substrate W. For example, the second distance may be about 0.1 mm to about 30 mm.

The cleaning processing gas is supplied to the second plasma generation unit 600 from the cleaning gas supply member 460. At this point, since the switch 664 is turned off, power is not applied to the antenna 640. The cleaning processing gas flows to the process chamber 100 while being in a gaseous state. The cleaning processing gas is uniformly distributed to the entire region in the processing space 122 through the injection hole 522 of the baffle 520. The first power source 560 applies power to the second electrode 540. At this point, the baffle 520 acts as an anode and plasma is generated from the cleaning processing gas in the edge region of the substrate W.

Since the plasma sheath region B is formed between the substrate W and the baffle 520, the center region of the substrate W is not exposed to plasma. Meanwhile, the edge region of the substrate W is outside the plasma sheath region B and is exposed to the plasma. Thus, since plasma treatment is performed only in the edge region of the substrate W except for the center region of the substrate W, the edge region of the substrate W is cleaned by the plasma. In an exemplary embodiment, during the edge region cleaning process, an internal temperature of the process chamber 100 may be about 30 to about 60 degrees centigrade and an internal pressure of the process chamber 100 may be maintained at hundreds of milliTorr (mTorr). However, the temperature and the pressure are not limited thereto.

Then, a back-surface cleaning process is performed (S44). Byproducts and particles remaining on a back surface of the substrate W are removed during the back-surface cleaning process.

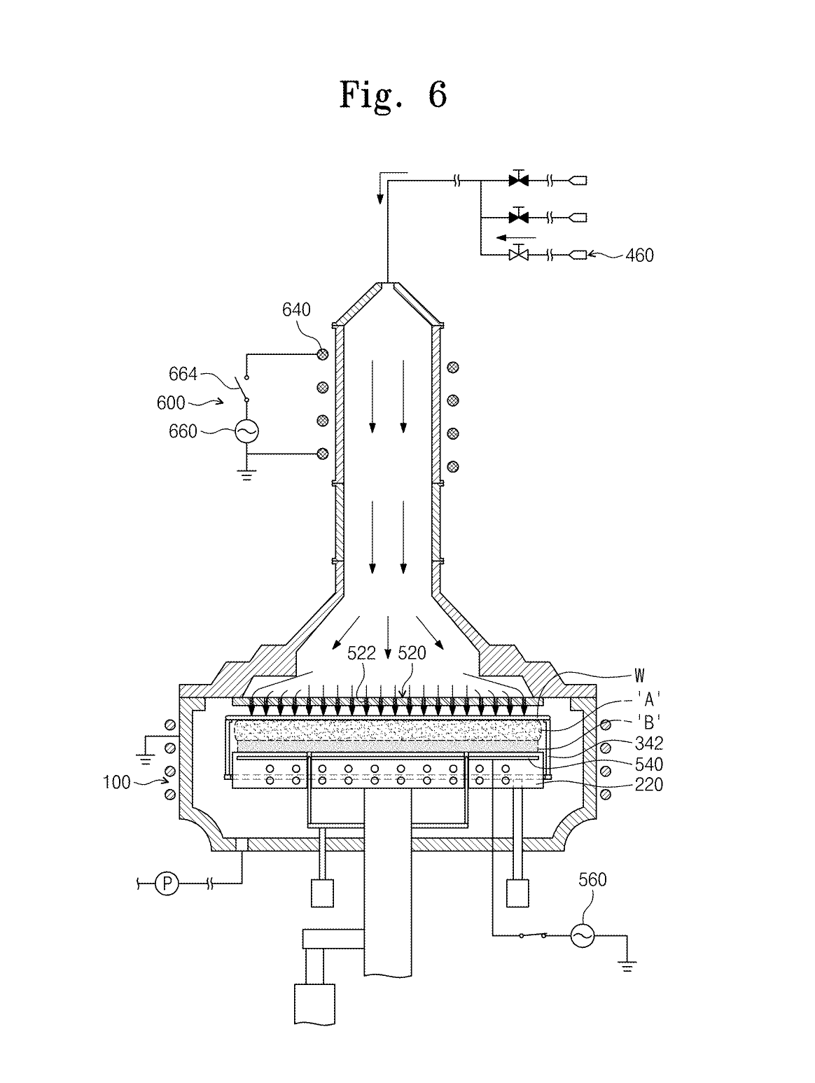

At this point, the support plate 220 and the baffle 520 may be kept at the second distance. However, the distance between the support plate 220 and the baffle 520 is not limited thereto. Referring to FIG. 6, the substrate W is lifted from the support plate 220 by the support assembly 340. If the substrate W is supported by the lift pin 322 during the back-surface cleaning process, poor cleaning may occur in a region that is in contact with the lift pin 322. However, if the edge region of the substrate W is supported by the support pin 342, the entire center region of the substrate W is cleaned. A distance between the substrate W and the support plate 220 is longer than the plasma sheath region B.

The cleaning processing gas is supplied to the second plasma generation unit 600. At this point, the switch 664 is turned off and power is not applied to the antenna 640. The cleaning processing gas flows to the process chamber 100 while being in a gaseous state. The cleaning processing gas is uniformly distributed the entire region inside the housing 120 through the injection hole 522 of the baffle 520. The cleaning processing gas is supplied into the process chamber 100, and the second power source 660 applies power to the second electrode 540. In this case, the substrate W acts as an anode and plasma is generated from the cleaning processing gas between the substrate W and the support plate 220. Thus, a bottom surface of the substrate W is exposed to the plasma to be cleaned by the plasma. In an exemplary embodiment, during the back-surface cleaning process, the internal temperature of the process chamber 100 may be about 30 to about 60 degrees centigrade and the internal pressure of the process chamber 100 may be hundreds of milliTorr (mTorr). However, the temperature and the pressure are not limited thereto.

Then, the substrate W is taken out from the process chamber 100 (S50). The lift pin 226 is disposed to protrude upwardly from the support plate 220. The transfer robot enters the process chamber 100, and elevation of the transfer robot allows the substrate W to be taken over to the transfer robot. The transfer robot travels to the outside of the process chamber 100.

In the above-described embodiment, the edge cleaning process is followed by the back-surface cleaning process. However, the back-surface cleaning process may be followed by the edge cleaning process.

In the foregoing embodiment, during the etching process and the ashing process, plasma is primarily generated from the etching processing gas and the ashing processing gas in the second plasma generation unit 600 and plasma is secondarily generated inside the process chamber 100 by the first plasma generation unit 100. Alternatively, during the etching process, application of power to the antenna 640 from the second power source 660 may be cut off, the etching processing gas may be supplied into the process chamber 100 while being not in a plasma state but in a gaseous state, and plasma may be generated inside the process chamber 100 by the first plasma generation unit 500. During the ashing process, application of power to the second electrode 540 from the first power source 560 may be cut off and plasma may be generated from the ashing processing gas only by the second plasma generation unit 600.

In the foregoing embodiment, the cleaning process includes an edge cleaning process and a back-surface cleaning process. However, the cleaning process may include only one of the edge cleaning process and the back-surface cleaning process.

In the foregoing embodiment, the substrate treating method includes an etching process, an ashing process, and a cleaning process. However, the substrate treating method may include only two of the above three processes. For example, the substrate treating method may include only the etching process and the ashing process. Alternatively, the substrate treating method may include only the ashing process and the cleaning process.

If the substrate treating method does not include a back-surface cleaning process, a support plate may optionally be provided with a size corresponding to that of a substrate or a support assembly may not be provided. In addition, if the substrate treating method does not include an edge cleaning process, a baffle may optionally be provided with a size corresponding to that of a substrate.

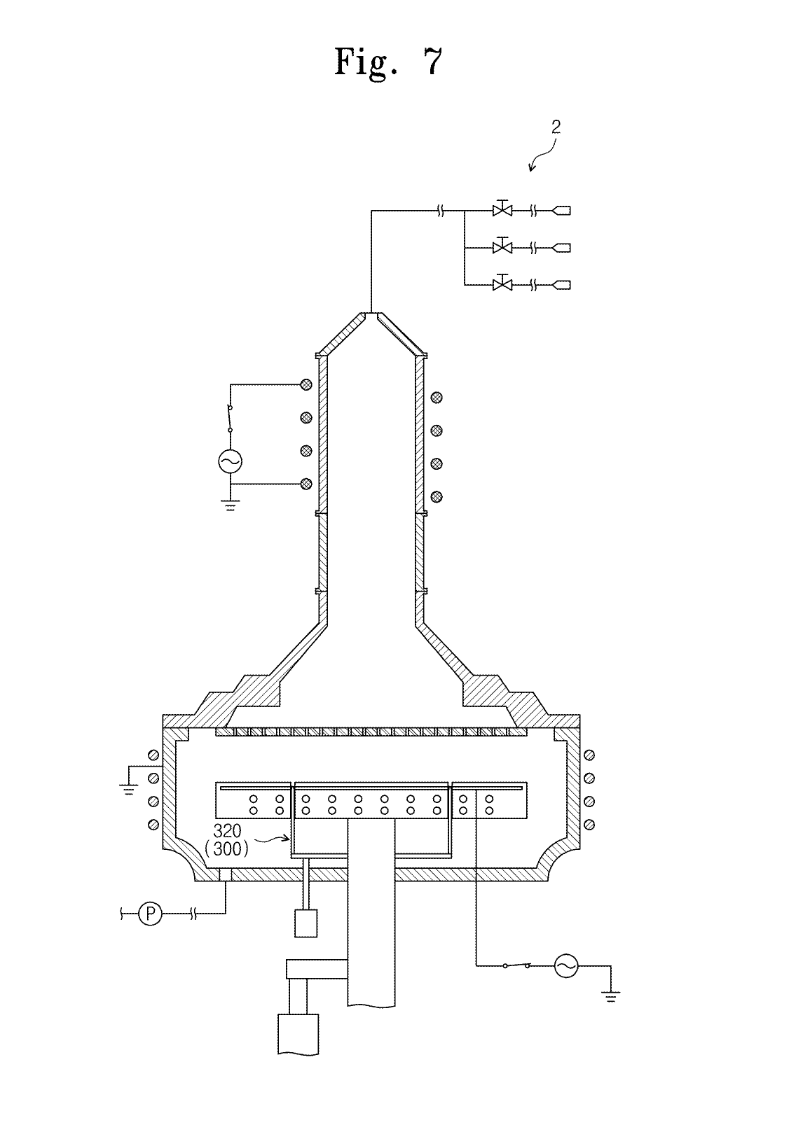

FIG. 7 illustrates a substrate treating apparatus 2 according to a modified embodiment of the inventive concept. As illustrated, a lift unit 300 includes a lift assembly 320. The substrate treating apparatus 2 does not include a support assembly shown in FIG. 1. In this case, takeover/reception of a substrate W to/from a transfer robot and lift and support of the substrate W during a back-surface cleaning process may be done by the lift assembly 320.

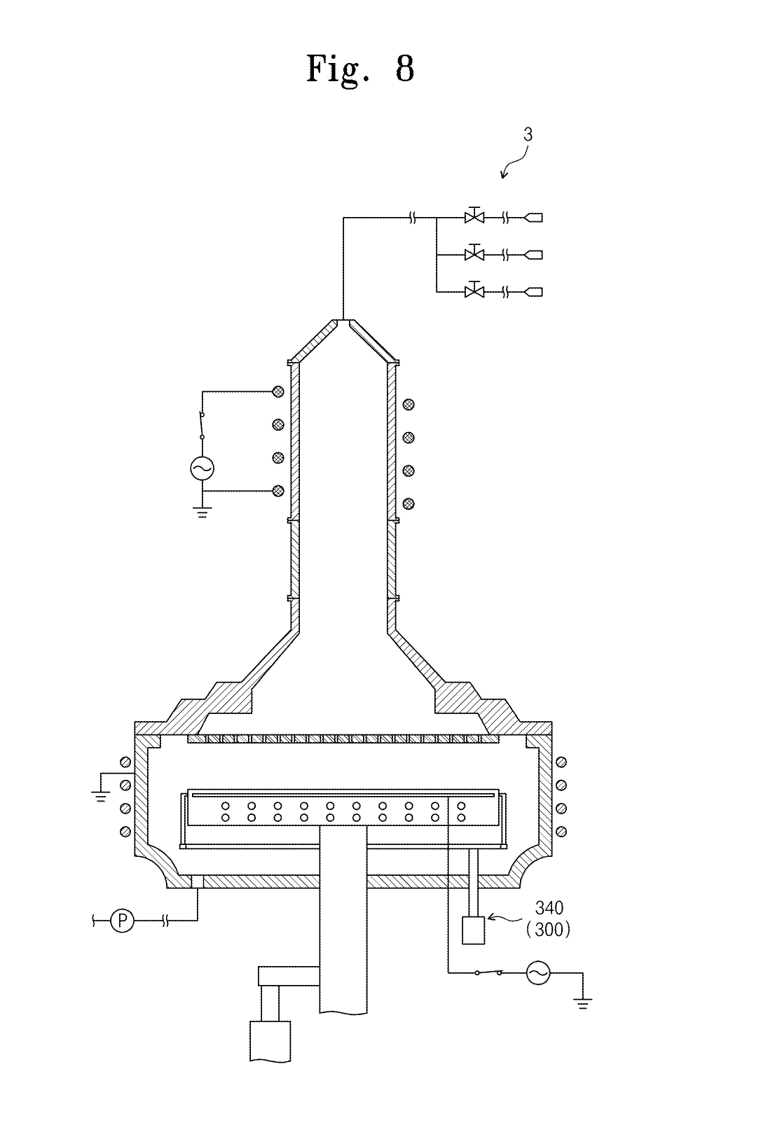

FIG. 8 illustrates a substrate treating apparatus 3 according to another modified embodiment of the inventive concept. As illustrated, a lift assembly 300 includes a support assembly 340. The substrate treating apparatus 3 does not include a lift assembly 3 shown in FIG. 1. In this case, takeover/reception of a substrate W to/from a transfer robot and lift and support of the substrate W during a back-surface cleaning process may be done by the support assembly 340.

When the substrate treating apparatus 2 or 3 in FIG. 7 or 8 is used, the lift unit 300 includes either one of a lift assembly and a support assembly. Therefore, the substrate treating apparatus 2 or 3 has a simpler configuration than the substrate treating apparatus 1 in FIG. 1. When the substrate treating apparatus 2 in FIG. 7 is used, back-surface cleaning may be done on the entire center region of a substrate W during a back-surface cleaning process. When the substrate treating apparatus 3 in FIG. 8 is used, up/down operations of a substrate W may be stably done because the center region of the substrate W is supported by support pins 342.

In the substrate treating apparatus 1 in FIG. 1, a cleaning processing gas is supplied into the process chamber 100 through the gas port 622 of the second plasma generation unit 600. However, the cleaning processing gas may be directly supplied into the process chamber 100. In this case, a cleaning gas supply line may be directly connected to the cover 140 of the process chamber 100 or the housing 120 of the process chamber 100.

While the inventive concepts have been particularly shown and described with reference to exemplary embodiments thereof, it will be apparent to those of ordinary skill in the art that various changes in form and detail may be made therein without departing from the spirit and scope of the inventive concepts as defined by the following claims.

What is claimed is:

1. A substrate treating method comprising:
sequentially performing at least two of an etching process, an ashing process, and a cleaning process while a substrate is provided inside the same process chamber,
wherein the etching process is performed inside the process chamber by generating plasma from an etching processing gas using a first plasma generation unit,
wherein the ashing process is performed outside the process chamber by generating plasma from an ashing processing gas using a second plasma generating unit and supplying the plasma into the process chamber, and
wherein the cleaning process is performed inside the process chamber by generating plasma from a cleaning processing gas using the first plasma generation unit.

2. The substrate treating method of claim 1, wherein the etching process further comprises primarily generating plasma outside the process chamber using the second plasma generation unit.

3. The substrate treating method of claim 1, wherein the ashing process further comprises secondarily generating plasma inside the process chamber using the first plasma generation unit.

4. The substrate treating method of claim 2, wherein a baffle where an injection hole is vertically formed is provided inside the process chamber, the baffle being grounded, and
wherein the etching processing gas or the ashing processing gas are supplied to the substrate through the injection hole of the baffle.

5. The substrate treating method of claim 1, wherein the first plasma generation unit comprises a first electrode provided in the process chamber and a second electrode provided in the process chamber to face the first electrode, the first electrode including a grounded baffle where an injection hole is formed vertically therethrough and the second electrode being provided in a support plate to support the substrate,
wherein the cleaning process further comprises an edge cleaning process to clean an edge region of the substrate,
wherein the baffle has a size corresponding to that of a center region of the substrate and is disposed to face the center region of the substrate, and
wherein a distance between the substrate and the baffle is shorter than a plasma sheath region during the edge cleaning process.

6. The substrate treating method of claim 5, wherein the first plasma generation unit comprises a first electrode provided in the process chamber and a second electrode provided in the process chamber to face the first electrode, the first electrode including a grounded baffle where an injection hole is formed vertically therethrough and the second electrode being provided in a support plate to support the substrate,
wherein the cleaning process further comprises a back-surface cleaning process to clean a back surface of the substrate, and
wherein the substrate is spaced apart from the support plate at a longer distance than a plasma sheath region during the back-surface cleaning process.

7. The substrate treating method of claim 6, wherein the edge region of the substrate is support by a support pin provided at the outer circumference of the support plate during the back-surface cleaning process.

8. A substrate treating method comprising:
putting a substrate into a process chamber;
performing an etching process on the substrate by generating plasma from an etching processing gas inside process chamber;
performing an ashing process on the substrate by generating plasma from an ashing treating process outside the process chamber and supplying the plasma into the process chamber;
performing a cleaning process on the substrate by generating plasma from a cleaning processing gas inside the process chamber; and
taking out the substrate to the outside of the process chamber.

9. The substrate treating method of claim 8, wherein the cleaning process comprises an edge cleaning process to clean an edge region of the substrate,
wherein a grounded baffle where an injection hole is vertically formed is provided in the process chamber, the baffle having a size corresponding to that of a center region of the substrate, and
wherein a distance between the substrate and the baffle is shorter during the edge cleaning process than during the etching process and the ashing process.

10. The substrate treating method of claim 9, wherein the distance between the substrate and the baffle is shorter than a plasma sheath region during the edge cleaning process, and the distance between the substrate and the baffle is longer than the plasma sheath region during the etching process and the ashing process.

11. The substrate treating method of claim 8, wherein the cleaning process further comprises a back-surface cleaning process to clean a back surface region of the substrate,
wherein the etching process and the ashing process are performed on the substrate while the substrate is placed on a support plate, and
wherein the back-surface process is performed on the substrate while the substrate is spaced apart from the support plate.

12. The substrate treating method of claim 11, wherein the edge region of the substrate is supported by a support pin provided at the outer circumference of the support plate during the back-surface cleaning process.
